(19) United States
(12) Patent Application Publication
(10) Pub. No.: US 2024/0218506 A1
(43) Pub. Date: Jul. 4, 2024

(54) REMOTE SOLID REFILL CHAMBER

(71) Applicant: ASM IP Holding B.V., Almere (NL)

(72) Inventors: Eric James Shero, Phoenix, AZ (US); Jonathan Bakke, Phoenix, AZ (US); Arjav Prafulkumar Vashi, Tempe, AZ (US); Todd Robert Dunn, Cave Creek, AZ (US); Paul Ma, Scottsdale, AZ (US); Jacqueline Wrench, Mesa, AZ (US); Jereld Lee Winkler, Gilbert, AZ (US); Shuaidi Zhang, Chandler, AZ (US); Shubham Garg, Tempe, AZ (US); YoungChol Byun, Tempe, AZ (US)

(21) Appl. No.: 18/395,801

(22) Filed: Dec. 26, 2023

Related U.S. Application Data
(60) Provisional application No. 63/477,613, filed on Dec. 29, 2022.

(51) Int. Cl. C23C 16/448; C23C 16/455; C23C 16/52

(52) U.S. Cl. CPC C23C 16/448; C23C 16/45557; C23C 16/45561; C23C 16/52

(57) ABSTRACT

The substrate processing system includes a delivery vessel having a first inner volume, disposed in a first location on a substrate processing platform, a remote refill vessel in fluid communication with the delivery vessel via a chemical delivery line, the remote refill vessel comprising a second inner volume greater than the first inner volume and disposed in a second location remote from the substrate processing platform, and a first heating device or a first pressurizing device, or a combination thereof, proximate the remote refill vessel, operable to heat or pressurize, or a combination thereof, a chemical disposed in the remote refill vessel sufficient to change a phase of the chemical from a first phase to a second phase.

### CROSS-REFERENCE TO RELATED APPLICATIONS

This application is a nonprovisional of, and claims priority to and the benefit of, U.S. Provisional Patent Application No. 63/477,613, filed Dec. 29, 2022 and entitled “REMOTE SOLID REFILL CHAMBER,” which is hereby incorporated by reference herein.

### FIELD OF THE DISCLOSURE

The present disclosure relates generally to semiconductor processing equipment and specifically to method, system and apparatus for refilling a chemical precursor delivery vessel.

### BACKGROUND OF THE DISCLOSURE

Semiconductor manufacturing processes such as chemical vapor deposition (CVD) and atomic layer deposition (ALD) involve deposition of thin film on a semiconductor wafer (also referred to herein as a “substrate”). During processing, the wafer is exposed to one or more precursors in a reaction chamber to deposit the thin layers of material. The precursor source is typically stored in delivery vessels onboard a processing tool and delivered to the reaction chamber from the delivery vessels. In order to reduce the need to service and change out delivery vessels delivery vessels are being made progressively larger. However, even large delivery vessels eventually empty and need to be swapped out requiring down-time and possibly quality or safety excursions. Such systems have generally been accepted for their intended purpose. However, there remains a need for improved methods, systems and apparatus for reducing the need to service and change out delivery vessels. The present disclosure provides a solution to this need.

### SUMMARY OF THE DISCLOSURE

A method for coupling a delivery vessel to a remote refill vessel is provided. The method includes, coupling a delivery vessel disposed at a first location on a substrate processing platform to a remote refill vessel disposed in a second location remote from the substrate processing platform, storing a chemical in the remote refill vessel in a first phase, changing a phase of the chemical in the remote refill vessel to a second phase, and transporting the chemical in the second phase, to the delivery vessel. The method may further include that changing the phase of the chemical further comprises heating the chemical or pressurizing the chemical, or a combination thereof.

In addition to one or more of the features described above, or as an alternative, further examples may include that changing the phase of the chemical further comprises sublimating the chemical at a first temperature below a melting point of the chemical. The method may further include that transporting the chemical further comprises receiving the chemical in the delivery vessel at a top portion of the delivery vessel in the second phase, and heating the chemical to a second temperature or pressurizing the chemical, or a combination thereof, to change the phase of the chemical to a third phase. The method may further include receiving the chemical on a bottom surface of the delivery vessel in the third phase and modifying the temperature of the chemical to change the chemical to a fourth phase. In an example, the third phase may be liquid and the fourth phase may be solid.

In addition to one or more of the features described above, or as an alternative, further examples may include maintaining a temperature gradient within an inner volume of the delivery vessel wherein the top portion of the delivery vessel is at a higher temperature than the bottom surface. The method may further include simultaneously changing the chemical to the third phase in the top portion of the delivery vessel and storing the chemical in the fourth phase on the bottom surface of the delivery vessel.

In addition to one or more of the features described above, or as an alternative, further examples may include that changing the phase of the chemical further comprises liquifying the chemical at a first temperature above a melting point of the chemical. The method may further include that transporting the chemical further comprises increasing a pressure on the chemical subsequent to the liquification by exposing the chemical to a pressurized gas within a volume of the remote refill vessel, receiving the chemical in the delivery vessel at a bottom portion of the delivery vessel in the second phase, and heating the chemical to a second temperature above the first temperature.

A substrate processing system is provided. The substrate processing system includes a delivery vessel having a first inner volume, disposed in a first location on a substrate processing platform, a remote refill vessel in fluid communication with the delivery vessel via a chemical delivery line, the remote refill vessel comprising a second inner volume greater than the first inner volume and disposed in a second location remote from the substrate processing platform, and a first heating device or a first pressurizing device, or a combination thereof, proximate the remote refill vessel, operable to heat or pressurize, or a combination thereof, a chemical disposed in the remote refill vessel sufficient to change a phase of the chemical from a first phase to a second phase.

In addition to one or more of the features described above, or as an alternative, further examples may include that the chemical delivery line is coupled to a second heating device operable to maintain the chemical delivery line at a transport temperature higher than a phase change temperature of the chemical. The substrate processing system may include that the delivery vessel further comprises a third heating device, a second pressurizing device or a cooling device, or a combination thereof, wherein the chemical delivery line is coupled to the delivery vessel via an inlet valve disposed in a top portion or a bottom portion of the delivery vessel.

In addition to one or more of the features described above, or as an alternative, further examples may include at least one sensor disposed in the chemical delivery line, the delivery vessel or the remote refill vessel, or a combination thereof, to monitor a temperature of the chemical and generate sensor data based on the monitoring, and at least one controller communicatively coupled to the at least one sensor and communicatively coupled to the first heating device, the second heating device, the third heating device, the first pressurizing device, the second pressurizing device or the cooling device, or a combination thereof, the at least one controller configured to receive the sensor data and adjust the first heating device, the second heating device, the third heating device, the first pressurizing device, the second pressurizing device or the cooling device, or a combination thereof, based on the sensor data. The substrate processing system may include that the inlet valve is disposed in the top portion of the delivery vessel and the third heating device or the second pressurizing device, or a combination thereof are configured to apply, respectively, heat or pressure, or a combination thereof, to the chemical upon entry into an interior volume of the delivery vessel, sufficient to change the phase of the chemical from the second phase to a third phase.

In addition to one or more of the features described above, or as an alternative, further examples may include that the cooling device is disposed at the bottom portion of the delivery vessel to cool a bottom interior surface to change a third phase of the chemical to a fourth phase. The substrate processing system may include that the first phase is solid, the second phase is gas, the third phase is liquid, and the fourth phase is solid.

In addition to one or more of the features described above, or as an alternative, further examples may include that the inlet valve is coupled to the bottom portion of the delivery vessel, wherein the third heating device is disposed at a base portion of the delivery vessel and is configured to heat the chemical upon entry into an interior volume of the delivery vessel to maintain the second phase of the chemical during refill of the delivery vessel. The substrate processing system may include that the first phase is a solid phase and the second phase is a liquid phase.

In addition to one or more of the features described above, or as an alternative, further examples may include that the cooling device comprises a cooling coil, disposed on an outer surface of the delivery vessel having a pitch that is varied along a longitudinal axis of the delivery vessel wherein the pitch is most dense proximate the bottom portion of the delivery vessel, a coolant inlet coupled to the cooling coil, disposed proximate the bottom portion of the delivery vessel and a coolant outlet coupled to the cooling coils and disposed opposite the coolant inlet.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram illustrating an example substrate processing system that includes a delivery vessel disposed on a substrate processing platform.

FIG. 2 is a schematic diagram illustrating an example refill subassembly of substrate processing system depicted in FIG. 1.

FIG. 3A is a schematic diagram illustrating an example delivery vessel and lid coupled to a top portion of the delivery vessel, as shown in FIG. 1.

FIG. 3B is an exploded schematic diagram illustrating an example lid depicted in FIG. 1.

FIG. 4 is a schematic diagram illustrating an example delivery vessel comprising cooling device and varied pitch cooling coils.

FIG. 5 is a flowchart illustrating an example of a solid source refill process.

FIG. 6 is a schematic diagram illustrating an example substrate processing system.

FIG. 7 is a schematic diagram illustrating an example refill subassembly of a substrate processing system depicted in FIG. 6.

FIG. 8 is a flowchart illustrating an example solid source refill process.

FIG. 9 is a flowchart illustrating an example solid source refill process.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

A chemical reactant or solid source delivery system can include a delivery vessel and a heater (e.g., a radiant heat lamp, resistive heater, and/or the like). The vessel includes the source precursor (which may also be referred to as “chemical” or “chemical precursor”), and which can be a solid (e.g., in powder form) or liquid. The heater heats up the vessel to facilitate the vaporization and/or sublimation of the reactant in the vessel. The vessel can have an inlet and an outlet for the flow of a carrier gas through the vessel. The carrier gas may be inert, for example, nitrogen, argon, or helium. Generally, the carrier gas conveys reactant vapor (e.g., evaporated or sublimated chemical reactant) along with it through the vessel outlet and ultimately to a substrate reaction chamber. The vessel typically includes isolation valves for fluidly isolating the contents of the vessel from the vessel exterior. One isolation valve may be provided upstream of the vessel inlet, and another isolation valve may be provided downstream of the vessel outlet. The delivery vessel of some embodiments comprises, consists essentially of, or consists of a sublimator. As such, wherever a “delivery vessel” is mentioned herein, a sublimator (such as a “solid source chemical sublimator”) is also expressly contemplated.

Chemical vapor deposition (CVD) is a known process in the semiconductor industry for forming thin films of materials on substrates such as silicon wafers. In CVD, reactant vapors (including “precursor gases”) of different reactant chemicals are delivered to one or more substrates in a reaction chamber. In many cases, the reaction chamber includes only a single substrate supported on a substrate holder (such as a susceptor), with the substrate and substrate holder being maintained at a desired process temperature. In typical CVD processes, mutually reactive reactant vapors react with one another to form thin films on the substrate, with the growth rate being related to the temperature and the amounts of reactant gases.

In some applications, the reactant gases are stored in a reactant delivery vessel. In such applications, the reactants are often gaseous at standard pressures and temperatures of around 1 atmosphere and room temperature. Examples of such gases include nitrogen, oxygen, hydrogen, and ammonia. However, in some cases, the vapors of source chemicals (“precursors”) that are liquid or solid (e.g., hafnium chloride, hafnium oxide, zirconium dioxide, etc.) at standard pressure and temperature are used. For some solid substances (referred to herein as “solid source precursors”, “solid chemical reactants”, or “solid reactants”), the vapor pressure at room temperature is so low that they are typically heated and/or maintained at very low pressures to produce a sufficient amount of reactant vapor for the reaction process. Once vaporized (e.g., sublimed or evaporated), keeping the vapor phase reactant at or above the vaporizing temperature through the processing system can prevent undesirable condensation in the valves, filters, conduits, and other components associated with delivering the vapor phase reactants from one location to another, for example from the delivery vessel to the reaction chamber. Vapor phase reactants from such naturally solid or liquid substances are useful for chemical reactions in a variety of other industries.

Atomic layer deposition (ALD) is another known process for forming thin films on substrates. In many applications, ALD uses a solid and/or liquid source chemical as described herein. ALD is a type of vapor deposition wherein a film is built up through self-saturating reactions performed in cycles. The thickness of the film is determined by the number of cycles performed. In an ALD process, gaseous reactants are supplied, alternatingly and/or repeatedly, to the substrate or wafer to form a thin film of material on the wafer. One reactant adsorbs in a self-limiting process on the wafer. A different, subsequently pulsed reactant reacts with the adsorbed material to form a single molecular layer of the desired material. Decomposition may occur through mutual reaction between the adsorbed species and with an appropriately selected reagent, such as in a ligand exchange or a gettering reaction. In some ALD reactions, no more than a molecular monolayer forms per cycle. Thicker films are produced through repeated growth cycles until the target thickness is achieved. In some ALD reactions, mutually reactive reactants are kept separate in the vapor phase with intervening removal processes between substrate exposures to different reactants.

Remote refill vessels and/or delivery vessels may be supplied with gas lines extending from the inlet and outlet, isolation valves on the lines, and fittings on the valves, the fittings being configured to connect to the gas flow lines of the remaining substrate processing platform. It is desirable to provide a number of additional heaters for heating the various valves and gas flow lines between the reactant delivery vessel and the reaction chamber, to prevent the reactant liquid or vapor from solidifying or condensing and depositing on such components. Accordingly, the gas and/or liquid conveying components between the remote refill vessel, delivery vessel and the reaction chambers may be maintained at a temperature above the vaporization/condensation/sublimation temperature of the reactant.

Multiple remote refill vessels may be included for filling the delivery vessel with source precursor as described herein. Conventionally, delivery vessels are removed and refilled from a substrate processing platform, which can lead to downtime and a loss of wafer production. The remote refill vessels can reduce a need to replace or refill a sublimator. Instead, the remote refill vessels can be used to automatically and/or continuously supply a delivery vessel with chemicals such as source precursor. A remote refill vessel system may include one or more remote refill vessels. Furthermore, remote refill vessels in accordance with embodiments herein can be disposed in a location remote to the substrate processing platform, for example, in a sub-fab, or other remote location. Thus, remote refill vessels volumes are not subject to size limitations of vessels disposed on the substrate processing platform.

In some examples, remote refill vessel may be disposed in a location that is spaced apart from a substrate processing platform (or “tool”). For example, a remote refill vessel may be located in another room from the substrate processing platform, across a cleanroom from the substrate processing platform, adjacent to the substrate processing platform or in a sub-fab. For the purposes of this disclosure a “sub-fab” is an area underneath a substrate processing platform. In some examples, it may be built into the floor of a cleanroom, in a building level lower than the level on which the substrate processing platform is disposed or may comprise a lower portion of substrate processing platform.

Having one or more remote refill vessels removed from a substrate processing platform system for refilling, the remote refill vessel reduce labor, downtime and safety excursions associated with replacing delivery vessels. Additional features are described herein with reference to various configurations.

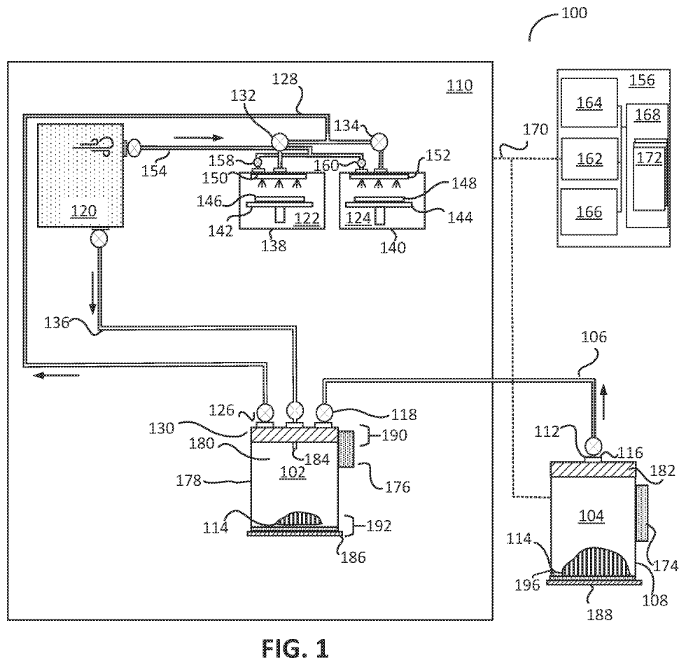

FIG. 1 is a schematic illustrating an example substrate processing system 100 that includes a delivery vessel 102 disposed on substrate processing platform 110. Substrate processing platform 110 includes one or more reactors 138 and 140 including respective reaction chambers 122 and 124. Reactors 138 and 140 include respective susceptors 142 and 144 to hold respective substrates 146 and 148 during processing. Substrate processing platform 110 includes gas distribution systems 150 and 152 to distribute one or more reactants to respective surfaces of substrates 146 and 148. Substrate processing platform 110 may include a vacuum source (not shown) for controlling vacuum pressure in one or more of reaction chambers 122 and 124. A reactant source may feed a gas-phase reactant, generated from a solid precursor source delivery vessel 102 into gas-phase reactors. Reaction chambers 138 and/or 140 may be gas-phase reactors. The solid source delivery vessel 102 may contain chemical 114 comprising a chemical reactant such as source chemicals or precursor including but not limited to HfCl4, ZrCl4, AlCl3, TaF5, MoF5, SiI4 or the like or combinations thereof. Chemical 114 may be solid under standard conditions (i.e., room temperature and atmospheric pressure). A carrier gas source 120 may be coupled to delivery vessel 102 via chemical delivery line 136 and may hold a carrier gas. Carrier gas source 120 may be fluidly coupled to reaction chambers 122 and 124 via chemical delivery line 154 and valves 158 and 160. In an example, valves 158 and 160 are controlled by one or more controllers. When introduced into delivery vessel 102, the carrier gas helps transport vaporized and/or sublimed chemical reactants through vessel outlet valve 126 to substrate reaction chamber 122 and/or 124. Chemical delivery line 128 may comprise valves 132 and 134 for controlling fluid communication of chemical 114 and/or carrier gas from delivery vessel 102 to respective reaction chambers 122 and 124.

In an example, delivery vessel 102 may be coupled to a remote refill vessel 104 via a chemical delivery line 106. Remote refill vessel 104 may be located distant laterally, above or below delivery vessel 102 and/or substrate processing platform 110, for example in a sub-fab located beneath substrate processing platform 110.

Remote refill vessel 104 may contain refill chemical 114 comprising a precursor or source chemical, which may be solid under standard conditions (i.e., room temperature and atmospheric pressure). Remote refill vessel 104 may be a bulk refill container that may have a larger chemical capacity within housing 108 than delivery vessel 102 as it may not be restrained by dimension restrictions associated with substrate processing platform 110. For example, remote refill vessel 104 may have at least 1.5×, 2×, 3×, 4×, 5×, 10×, or 20× the capacity of delivery vessel 102. Other capacities are possible and claimed subject matter is not limited in this regard.

Chemical delivery line 106 may extend between outlet valve 116 of remote refill vessel 104 and inlet valve 118 of delivery vessel 102. Inlet valve 118 may be disposed in lid 130 of delivery vessel 102. Outlet valve 116 may be disposed in lid 182 of remote refill vessel 104. Outlet valve 116 and inlet valve 118 may control fluid communication of chemical 114 from remote refill vessel 104 to delivery vessel 102.

Remote refill vessel 104 may be equipped to vaporize (e.g., sublimate, evaporate) chemical 114 and may subsequently pass vaporized or sublimated chemical 114 to delivery vessel 102 via chemical delivery line 106. In an example, remote refill vessel 104 may be proximate a heating device 174 disposed exterior to and in thermal communication with lid 182 and/or housing 108. Housing 108 may be made of a thermally conductive material (e.g., stainless steel) and may be configured to transfer heat from heating device 174 to a lid 182 and/or an interior volume of remote refill vessel 104. Heating device 174 may be configured to heat chemical 114 to a temperature sufficient to change the phase of chemical 114, such as to vaporize and/or sublimate chemical 114 in order to transfer chemical 114 via chemical delivery line 106 to delivery vessel 102. Heating device 174 may comprise any of a variety of heating devices such as heaters, heating jackets, heating blocks, and/or radial heater known to those of skill in the art and claimed subject matter is not limited in this regard.

Remote refill vessel 104 may be configured to store chemical 114 between refill operations. A cooling device 188 may be coupled to a bottom portion of remote refill vessel 104. Cooling device 188 may cool bottom surface portion 196 so as to maintain chemical 114 in solid form prior to sublimation. Cooling device 188 may comprise a chill plate, cooling coils, variable pitch cooling coils, a cooling jacket, cooling fans, a Peltier cooler or integrated coolant channels circulating coolant or the like or any combination thereof.

Remote refill vessel 104 may be configured to operate at a selected temperature. For example, the operating temperature may be determined based on a desired subliming rate of the chemical precursor/reactant. In some examples, the operating temperature is in the range of about 10° C. to about 500° C. The selected operating temperature may depend, of course, upon the chemical to be vaporized or sublimed. Other temperature ranges are possible and claimed subject matter is not limited in this regard.

Delivery vessel 102 may receive chemical 114 in gas phase via chemical delivery line 106 from remote refill vessel 104. Chemical delivery line 106 may be disposed at the top portion 190 of delivery vessel 102, for example, in lid 130. In an example, lid 130 and inlet valve 118 may be configured to liquify chemical 114 as it passes into delivery vessel 102 so as to cause liquified chemical 114 to drip, for example from inlet valve 184, to the bottom of delivery vessel 102 to solidify. Delivery vessel 102 may be thermally coupled to one or more heating devices 176 (e.g., heaters, heating jackets, heating blocks, and/or radial heater) and/or one or more cooling devices 186. Such heating or cooling devices serve to control or adjust the temperature of chemical 114 during refilling operations, material processing operations and storage of chemical 114. Cooling devices 186 may comprise, a chill plate, cooling coils, variable pitch cooling coils, a cooling jacket, cooling fans, a Peltier cooler or integrated coolant channels circulating coolant or the like or any combination thereof. As will be discussed in more detail, such heating and cooling devices 186 provide a temperature gradient within delivery vessel 102.

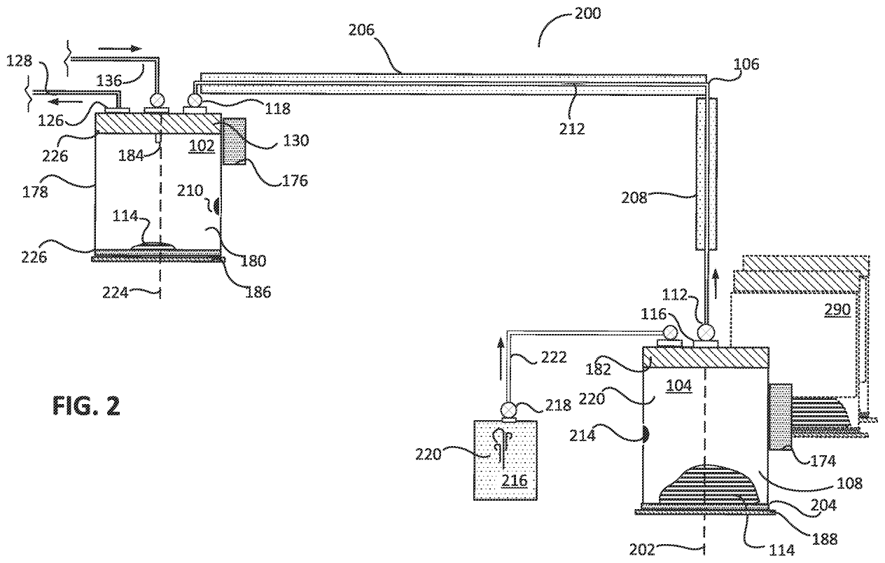

In an example, delivery vessel 102 may be proximate or coupled to a heating device 176 disposed exterior to and in thermal communication with housing 178 and/or lid 130 of delivery vessel 102. Housing 178 and/or lid 130 may be configured to transfer heat and/or pressure from heating device 176 to chemical 114 as it enters delivery vessel 102. Such applied heat and/pressure may liquify chemical 114 causing it to form droplets and fall to the bottom of delivery vessel 102. Delivery vessel 102 base 192 temperature may be cooled by a cooling device 186 (e.g., a cold plate) to a lower temperature than incoming chemical delivery line 106 (see FIG. 1), sidewalls of housing 178 or lid 130 of delivery vessel 102. This provides a temperature gradient along longitudinal axis 224 (see FIG. 2) where the highest temperature in the system may be at the top portion 190 of delivery vessel 102 and the lowest temperature in the system may be at the base 192. Liquid droplets formed as chemical 114 enters through lid 130 solidify upon contact with bottom surface at the base 192 of delivery vessel 102. During refill, chemical 114 will form a solid at the bottom of delivery vessel 102 and may be stored there until a material processing operation. Cooling device 186 may maintain a temperature at the base 192 of delivery vessel 102 sufficient to maintain chemical 114 in solid phase.

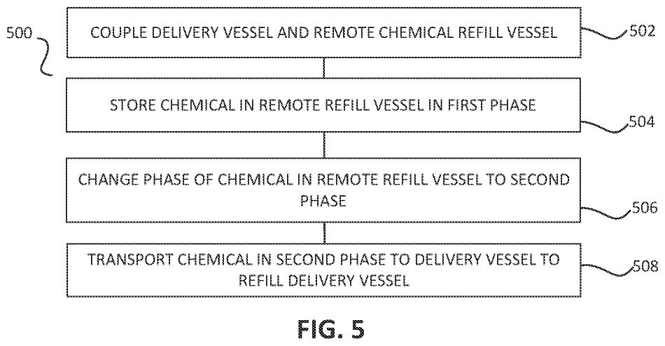

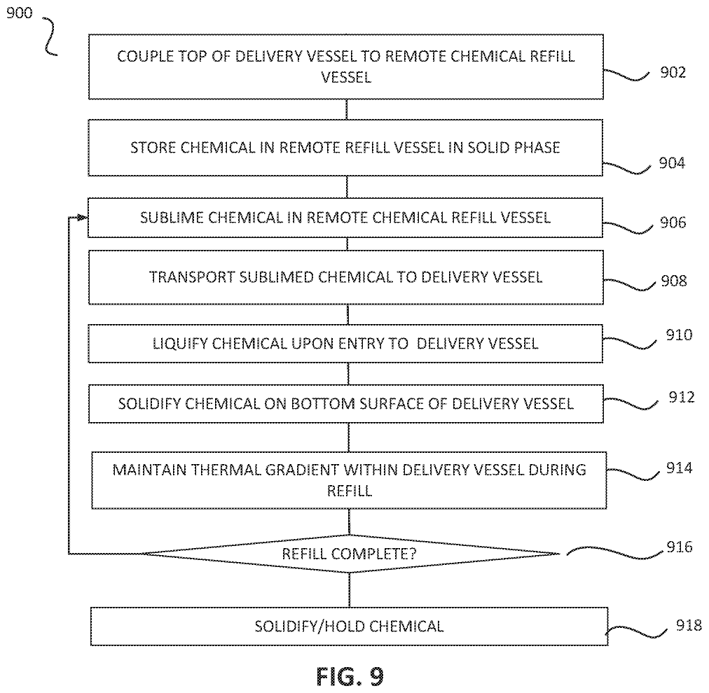

During a refilling operation (shown in FIG. 5 and FIG. 9), delivery vessel 102 may be configured to operate with a temperature gradient within the interior volume 180. For example, the operating temperature proximate top portion 190 may be determined based on a desired liquification rate of chemical 114 precursor/reactant. In some examples, the operating temperature is in the range of about 10° C. to about 500° C. The selected operating temperature may depend upon the chemical to be liquified as it enters delivery vessel 102. Likewise, delivery vessel 102 base 192 may be maintained at a lower temperature than the top portion 190 to solidify chemical 114 on base 192 to maintain the temperature gradient within delivery vessel 102. The selected operating base temperature again may depend upon the chemical to be solidified. Additionally, to prevent gaseous particles from solidifying in unwanted areas on the interior of delivery vessel 102, base 192 may be set to a temperature that is at least cooler than top portion 190. In an example, base 192 is the coolest location in the interior volume 180 of delivery vessel 102. Thus, the operating temperature at base 192 may be well below a melting point of chemical 114.

The temperature gradient extends between the base 192 and top portion 190 including lid 130. In an example, base 192 may be maintained at or below a first threshold temperature, while portion 190 may be maintained at or above a second threshold temperature that is greater than the first threshold temperature. For example, the base 192 and top portion 190 may be maintained at a difference in temperature (e.g., a difference between the second threshold temperature and the first threshold temperature). In an example, the difference in temperature between the base 192 and portion 190 may be at least about 1º C., about 5° C., about 10° C., about 20° C., about 40° C., about 80° C., or about 160° C., or any value therebetween, or fall within any range having endpoints therein. Other temperature differences are possible and claimed subject matter is not limited in this regard. The gradient can be disposed across an axial distance along longitudinal axis 224 (see FIG. 2) of about 1 inch, about 2 inches, about 4 inches, about 8 inches, about 16 inches, about 32 inches, about 64 inches, or about 128 inches, or any value therebetween, or fall within any range having endpoints therein. The gradient may be stepwise or linear. Other gradient dimensions are possible and claimed subject matter is not limited in this regard.

In an example, during a material processing operation, heating device 176 may be configured to heat chemical 114 to a temperature sufficient to change the phase of chemical 114, such as to vaporize and/or sublimate chemical 114. Once vaporized or sublimed, chemical 114 may be transported via chemical delivery line 128 to reaction chambers 122 and/or 124 for substrate processing. Prior to vaporization and/or sublimation, chemical 114 may be stored as a solid in delivery vessel 102. Alternatively, chemical 114 may be stored in liquid phase during or after refilling. Heating device 176 may be configured to heat delivery vessel 102 to a temperature sufficient to liquify chemical 114.

During material processing, delivery vessel 102 may be configured to operate at a selected temperature based on a desired subliming rate of chemical 114 precursor/reactants. In some examples, the operating temperature is in the range of about 10° C. to about 500° C. Other temperature ranges are possible and claimed subject matter is not limited in this regard.

Once depleted of chemical 114, delivery vessel 102 may be refilled from remote refill vessel 104. It may not be necessary to completely deplete delivery vessel 102 of chemical 114 prior to refilling from remote refill vessel 104.

In the illustrated example controller 156 includes a device interface 162, a processor 164, a user interface 166, and a memory 168. The device interface 162 connects the processor 164 to the wired or wireless link 170. The processor 164 may be operably connected to the user interface 166 (e.g., to receive user input and/or provide user output therethrough) and may be disposed in communication with the memory 168. The memory 168 includes a non-transitory machine-readable medium having a plurality of program modules 172 recorded thereon containing instructions that, when read by the processor 164, cause the processor 164 to execute certain operations. Among the operations are operations of a material layer deposition method and methods for refilling a delivery vessel 102 (shown in FIG. 5 and FIG. 9), as will be described. As will be appreciated by those of skill in the art in view of the present disclosure, the controller 156 may have a different arrangement in other examples and remain within the scope of the present disclosure.

FIG. 2 is a schematic diagram illustrating an example refill subassembly 200 of substrate processing system 100 depicted in FIG. 1. Refill subassembly 200 includes delivery vessel 102 coupled to remote refill vessel 104 via chemical delivery line 106. Remote refill vessel 104 may be configured to maintain a temperature gradient along a longitudinal axis 202 to store chemical 114 (e.g., precursor) in a solid state prior to being sublimed or vaporized. Base 204 of the remote refill vessel 104 may be at a relatively low temperature (e.g., to maintain the precursor as a solid). Lid 182 may reach relatively high temperatures to facilitate transportation to delivery vessel 102. Such temperatures are sufficient to at least cause chemical 114 to enter the vapor phase and minimize condensation in downstream flow path components such as: chemical delivery line 106, lid 182, outlet valve 116, and inlet valve 118.

In some examples, a carrier gas source 216 may be coupled to remote refill vessel 104 via chemical delivery line 222 and may supply carrier gas 220 to remote refill vessel 104. Valve 218 may control the flow of carrier gas 220. Carrier gas 220 may assist transport of the sublimated chemical 114 from the remote refill vessel 104 to delivery vessel 102.

In an example, heaters 206 and 208 may be coupled to chemical delivery line 106 to maintain a “transport temperature” which may be a vaporization temperature to prevent condensation during transport. Such vaporization temperatures may be above a phase change temperature (e.g., a sublimation temperature) of chemical 114. Heaters 206 and 208 may comprise heater jackets or other heating devices known to those of skill in the art and claimed subject matter is not limited in this regard. Heaters 206 and 208 may be wrapped around, coiled, envelop, or otherwise be disposed in close proximity to chemical delivery line 106. Chemical delivery line 106 may have very few angles or corners to discourage condensation. Valves, connection points and/or other interruptions in the chemical delivery line 106 may be minimized to the extent possible to offset a higher risk of condensation in chemical delivery line 106 due to the disposition of remote refill vessel 104 distant from (i.e., spaced apart) from substrate processing platform 110 (see FIG. 1).

In an example, one or more back-up remote refill vessels 290 may be co-located with remote refill vessel 104 to reduce downtime required to replace remote refill vessel 104 when depleted. When remote refill vessel 104 needs to be replaced, back-up remote refill vessels 290 may be quickly coupled to delivery vessel 102 via chemical delivery line 106 (or via a different chemical delivery line) to avoid downtime waiting for remote refill vessel 104 to be removed and replaced. Alternatively, back-up remote refill vessels 290 may be coupled to remote refill vessel 104 to refill vessel 104 at other opportune idle times, such as between refill operations or upstream events requiring downtime on the substrate processing platform 110.

In an example, the refilling process may be controlled manually and/or refill operations may be partially or fully automated using a variety of sensors for automated feedback control by a controller 156. For example, sensor 210 may be disposed adjacent to or within an interior volume 180 of delivery vessel 102, sensor 212 may be disposed within or adjacent to chemical delivery line 106 and sensor 214 may be disposed adjacent to or within an interior volume 220 of remote refill vessel 104. Sensors 210, 212, and 214 may monitor a variety of physical phenomenon such as, for example, acoustics, vibration, chemicals, moisture, flow, light, pressure, force, density, temperature and/or presence, or the like or any combinations thereof. Sensors 210, 212, and/or 214 may, for example, monitor a temperature gradient in delivery vessel 102 and/or monitor a temperature of the chemical 114 disposed in at least one of the chemical delivery line 106, delivery vessel 102 or the remote refill vessel 104, or a combination thereof. Sensors 210, 212, and/or 214 may alternatively or additionally monitor a temperature of or within chemical delivery line 106, delivery vessel 102 and/or remote refill vessel 104, or a combination thereof. Sensors 210, 212, and/or 214 may generate sensor data based on the monitoring and send the sensor data to controller 156 (see, FIG. 1) to adjust the monitored devices to change a monitored parameter (e.g., temperature). For example, controller 156 may adjust one or more of heating devices 174, 176, 206 and/or 208 and/or cooling devices 186 and 188 or a combination thereof based on the sensor data. In some embodiments, the electronics and/or computer elements for use in controlling one or more of reaction chamber 122, reaction chamber 124, delivery vessel 102 and/or remote refill vessel 104 can be found elsewhere in the system. For example, central controllers may control both apparatus of the one or more chambers themselves as well as control the valves that connect to the various vessels and any associated heating devices. One or more valves may be used to control the flow of gas throughout substrate processing system 100.

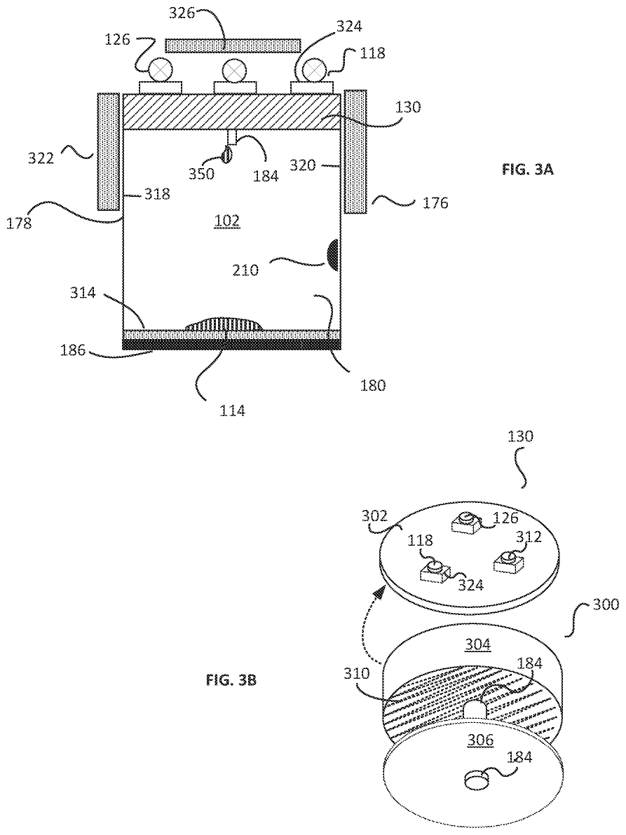

FIG. 3A is a schematic diagram illustrating an example delivery vessel 102 and lid 130 coupled to a top portion of delivery vessel 102, as shown in FIG. 1. In an example, lid 130 may be integral with the housing 178 or may simply rest on the housing 178 or may be removably or permanently attached to the housing 178. Lid 130 may be attached to housing 178 by friction (e.g., a threading), compressive force (e.g., clamps), screws or the like, or a combination thereof. In an example, lid 130 and housing 178 may be made of the same or different materials including but not limited to: stainless steel, high nickel alloys, aluminum, titanium, or the like or a combination thereof.

In an example, lid 130 may be configured to liquify chemical 114, upon entry into delivery vessel 102 via inlet valve 118. Inlet valve 118, porting block 324, one or more heaters 176, 322, and 326, outlet valve 184 and/or other hardware in lid 130 may be configured to apply heat and/or pressure sufficient to liquify chemical 114. For example, lid 130 may be thermally coupled to and heated by one or more heating devices such as, porting block 324 and/or heaters 176, 322, and/or 326. Heaters 176, 322, and/or 326 may comprise, for example, heaters, heating jackets, heating blocks, and/or radial heater. They may be disposed in close proximity to housing 178 and/or lid 130 to adjust the temperature of lid 130. Heat from lid 130, inlet valve 118, porting block 324, one or more heaters 176, 322, and 326, outlet valve 184 and/or other hardware in lid 130 may be transferred via radiation, conduction and/or convection to chemical 114 as it flows into and/or through lid 130 and passes into vessel 102. A temperature of lid 130, inlet valve 118, porting block 324, one or more heaters 176, 322, and 326, outlet valve 184 and/or other hardware in lid 130 may be at least at a melting point temperature sufficient to liquify chemical 114 from a gaseous state. Inlet valve 118, outlet valve 184 and/or other valves in fluid communication with a flow path of chemical 114 may apply heat and/or pressure to liquify and/or aid in liquification of chemical 114.

In an example, upon liquification chemical 114 may condense forming droplets 350 that fall to a bottom surface 314 of delivery vessel 102. Delivery vessel 102 base temperature may be cooled by a cooling device 186 (e.g., a cold plate) to a lower temperature than incoming chemical delivery line 106 (see FIG. 1) or the side walls 320 or lid 130 of delivery vessel 102. This provides the lowest temperature in the system, where the liquid solidifies upon contact with bottom surface 314.

FIG. 3B is an exploded schematic diagram of an example lid 130 showing top surface 302, side wall 304, gas flow path 310, and bottom surface 306. Lid 130 may comprise a chemical sublimator 300 in fluid communication with outlet valve 126 which may be coupled to one or more reaction chambers 122 and 124 (see FIG. 1). A gas flow path 310 may be adapted to allow the flow of gas therethrough. In some configurations, the gas flow path 310 may be serpentine.

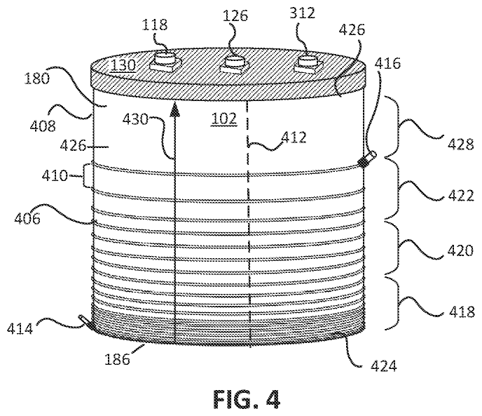

In an example, chemical 114 may enter interior portion 180 of delivery vessel 102 via outlet valve 184. Outlet valve 184 may be in fluid communication with inlet valve 118 and may be configured to apply heat and/or pressure sufficient to liquify chemical 114 so as to cause it to drip to a bottom surface 314 of delivery vessel 102. Chemical 114 may be in thermal contact with cooling device 186. Cooling device 186 may maintain a colder temperature at a lower portion of delivery vessel 102 to keep chemical 114 in solid phase during a refilling operation. In some examples other cooling devices may be used to maintain a desired temperature in a selected portion of delivery vessel 102 such as, for example, variable pitch cooling coils (see FIG. 4), cooling jacket, cooling fans, Peltier cooler, or integrated coolant channels circulating coolant within an interior portion of a delivery vessel wall, or a combination thereof.

FIG. 4 illustrates an example delivery vessel 102 comprising cooling device 186 and varied pitch cooling coils 406 disposed on a portion of an outer surface 408. Varied pitch cooling coils 406 assist in maintaining a temperature gradient 430 within delivery vessel 102. Temperature gradient 430 may be formed within the interior volume 180 of delivery vessel 102 from a first temperature at bottom portion 424 to a second temperature near the top portion 426 of delivery vessel 102, where the first temperature can be less than the second temperature.

As discussed with respect to FIG. 1, chemical 114 may be transported to delivery vessel 102 from a remote refill vessel 104 in vapor phase. Condensation of chemical 114 to a solid may be a temperature sensitive process. Chemical 114 (e.g., a chemical precursor) may first condense on the coldest location in delivery vessel 102 at the bottom portion 424 which may be cooled by cooling device 186 (e.g., a cold plate). This first condensation portion may act as a nucleation site for further chemical 114 entering delivery vessel 102 during filling. In contrast, lid 130 of delivery vessel 102 should be maintained at a higher temperature to ensure chemical 114 does not condense within openings in lid 130 such as inlet valve 118, outlet valve 126 and/or inlet valve 312. Thus, it is desirable to maintain thermal gradient 430 to encourage solidification of chemical 114 on cooled inner surface 314 at the bottom portion 424 of delivery vessel 102 and to prevent chemical 114 from solidifying in and around lid 130.

The pitch 410 of cooling coils 406 varies along a longitudinal axis 412 of delivery vessel 102 (“pitch” herein means a gap between adjacent spiral turns of cooling coils 406). For example, pitch 410 of cooling coils 406 may be denser (or most dense) or closer together at a first portion 418, than at a second portion 420, a third portion 422, and/or a fourth portion 428. Pitch 410 may gradually change. In other words, pitch 410 density may be high at the bottom portion 424 and may become less dense along longitudinal axis 412 from bottom portion 424 to top portion 426 of vessel 102. Varying the pitch 410 of cooling coils in this way may help maintain a temperature gradient 430 within delivery vessel 102.

Cooling coils 406 may be hollow to allow a coolant to flow therethrough. The coolant may be any of a variety of coolants known to those of skill in the art such as water, deionized water, glycol/water solutions, and dielectric fluid, or the like or a combination thereof. Coolant may enter cooling coils 406 at inlet 414 near the bottom portion 424 of delivery vessel 102 and may exit via outlet 416 higher up longitudinal axis 412. In this way the coolant may be coolest near bottom portion 424 to help maintain the thermal gradient 430. Cooling coils may be formed from a variety of thermally conductive materials including but not limited to stainless steel, aluminum, copper, or the like or combinations thereof.

FIG. 5 is a flow chart that depicts an embodiment of a solid source refill process 500, generally. Process 500 will be described with reference to FIGS. 1-4. Process 500 may begin at block 502, where delivery vessel 102 (see FIG. 1) may be coupled to a remote refill vessel 104. Delivery vessel 102 may be disposed at a first location on a substrate processing platform 110 and remote refill vessel 104 may be disposed in a second location remote from the substrate processing platform 110. In an example, the first location may be separated from the second location by a distance of about 1 ft. to about 20 ft., 20 ft. to about 100 ft., 100 ft. to about 200 ft., or 200 ft. to about 500 ft. Other distances are possible and claimed subject matter is not limited in this regard.

Delivery vessel 102 may be coupled to remote refill vessel 104 via chemical delivery line 106. Process 500 may move to block 504, where a chemical 114 (e.g., precursor) may be stored in remote refill vessel in a first phase. In an example, first phase may be solid phase. In another example, the first phase may be liquid or gas. At block 506, the phase of chemical 114 may be changed to a second phase by action of one or more components of remote refill vessel 104. Such action may comprise heating and/or pressurizing chemical 114. In an example, the first phase and the second phase are different. Process 500 may move to block 508 where chemical 114 may be transported to delivery vessel 102 in the second phase to refill delivery vessel 102 with chemical 114. Chemical 114 may be transported from remote refill vessel 104 to delivery vessel 102 by opening of chemical delivery line 106 wherein open chemical delivery line 106 puts the remote refill vessel 104 in fluid communication with the delivery vessel. After refill is complete chemical 114 from delivery vessel 102 may be transported to a reaction chamber 138 and/or 140 in fluid communication with delivery vessel 102 to process a substrate 146 and/or 148.

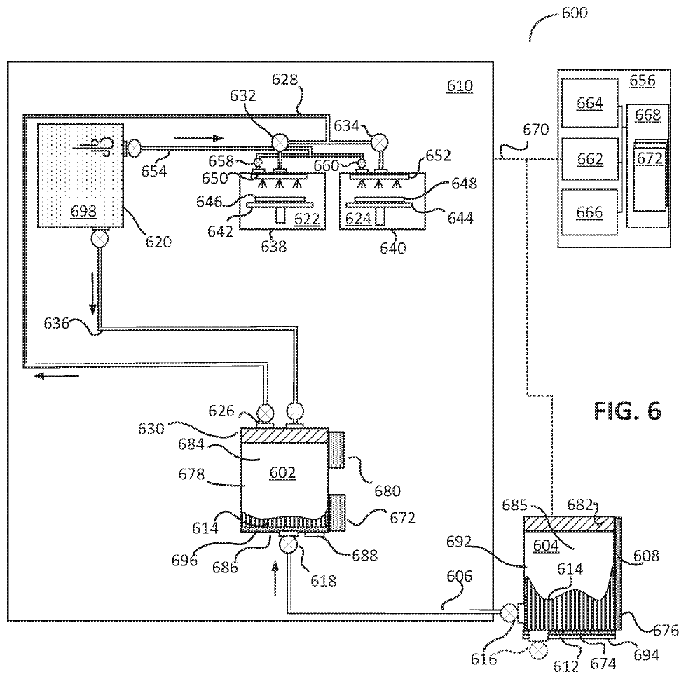

FIG. 6 is a schematic diagram illustrating an example substrate processing system 600 that includes a delivery vessel 602 disposed on substrate processing platform 610. Substrate processing platform 610 includes one or more reactors 638 and 640 including respective reaction chambers 622 and 624. Reactors 638 and 640 include respective susceptors 642 and 644 to hold respective substrates 646 and 648 during processing. Substrate processing platform 610 includes gas distribution systems 650 and 652 to distribute one or more reactants to respective surfaces of substrates 646 and 648. Substrate processing platform 610 may include a vacuum source (not shown) for controlling vacuum pressure in one or more of reaction chambers 622 and 624. A reactant source may feed a gas-phase reactant, generated from a solid precursor source delivery vessel 602 into gas-phase reactors 638 and/or 640. A carrier gas source 620 may also be fluidly coupled to reaction chambers 622 and 624 via chemical delivery line 654 and valves 658 and 660.

The solid source delivery vessel 602 may contain a precursor or source chemical (e.g., chemical 614), which may be solid under standard conditions (i.e., room temperature and atmospheric pressure).

In an example, delivery vessel 602 may be coupled to a remote refill vessel 604. Remote refill vessel 604 may be located distant laterally, above or below delivery vessel 602 and/or substrate processing platform 610. For example, remote processing vessel 604 may be disposed in a sub-fab located under substrate processing platform 610. Remote refill vessel 604 may comprise a bulk refill container and can be coupled to the delivery vessel 602 via a chemical delivery line 606.

Chemical delivery line 606 may extend between outlet valve 616 of remote refill vessel 604 and inlet valve 618 of delivery vessel 602. Inlet valve 618 may be disposed on a bottom portion 696 of delivery vessel 602. Outlet valve 616 may be disposed in a lower portion near or on the bottom portion 612 of remote refill vessel 604. Valves 616 and 618 may be configured to control the flow of chemical 614 from remote refill vessel 604 to delivery vessel 602.

Remote refill vessel 604 may have a larger chemical capacity within housing 608 than delivery vessel 602 as it may not be restrained by size restrictions within the substrate processing platform 610. For example, remote refill vessel 604 may have at least 1.5×, 2×, 3×, 4×, 5×, 10×, or 20× the capacity of delivery vessel 602. Other capacities are possible and claimed subject matter is not limited in this regard.

In an example, remote refill vessel 604 may contain refill chemical 614 comprising a precursor or source chemical, which may be solid under standard conditions (i.e., room temperature and atmospheric pressure). Remote refill vessel 604 may pass chemical 614 therein to delivery vessel 602 via chemical delivery line 606. Remote refill vessel 604 may be equipped to melt and/or liquify chemical 614 before passing through the chemical delivery line 606. In an example, remote refill vessel 604 may heat chemical 614 to a temperature above a melting point to prevent solidification in chemical line 606 to facilitate flow through the line and prevent clogging. Remote refill vessel 604 may have one or more heating devices 674 and/or 676 (e.g., heaters and/or valve ports) adapted to heat chemical 614 to at least a melting point temperature. Heating devices 674 and/or 676 may be proximate to or disposed on an exterior of remote refill vessel 602. Heating devices 674 and/or 676 may be in thermal communication with lid 682 and/or housing 608. For example, heating device 674 may be positioned proximate or coupled to bottom portion 612 of remote refill vessel 604 and heating device 676 may be positioned proximate or coupled to sidewalls 692 of housing 608. Lid 682 and housing 608 may be made of thermally conductive material (e.g., stainless steel) and may be configured to transfer heat from heating devices 674 and/or 676 to lid 682 and/or an interior volume 685 of remote refill vessel 604. Heating devices 674 and/or 676 may heat chemical 614 to a temperature sufficient to liquify it and to prevent solidification on lid 682 and sidewalls 692 during a refilling operation. Heating devices 674 and/or 676 may heat chemical 614 to a temperature above the melting point to further avoid solidification in chemical delivery line 606 during transfer to delivery vessel 602. This may facilitate transferring chemical 614 via chemical delivery line 606 to delivery vessel 602 with minimal clogging. In an example, chemical delivery line 606 outlet valve 616 may be disposed lower in remote refill vessel 604 or at the bottom portion 612 of the vessel 604. Heating devices 674 and/or 676 may comprise any of a variety of heating devices (e.g., heaters, heating jackets, heating blocks, and/or radial heater) known to those of skill in the art and claimed subject matter is not limited in this regard.

Remote refill vessel 604 may be configured to operate at an operating temperature. For example, the operating temperature may be determined based on a desired melting/liquification rate of the chemical precursor/reactant. In some examples, the operating temperature is in the range of about 10° C. to about 500° C. Other temperature ranges are possible and claimed subject matter is not limited in this regard.

In an example, delivery vessel 602 may be thermally coupled to one or more heating devices 672, 680 and/or 686 disposed on exterior of housing 678. Heating device 686 may be disposed on a bottom portion 696 of delivery vessel 602. Heating devices 680 and 672 may be disposed on a sidewall of housing 678. Such heating devices serve to control or adjust the temperature of chemical 614 during refilling operations, material processing operations and storage of chemical 614.

In an example, as chemical 614 enters delivery vessel 602 via valve 618, it may be kept at a temperature above a melting point and/or above a temperature it was heated to by remote refill vessel 604 to prevent solidification during the refilling operation. Heating devices 672, 680 and/or 686 may be adapted to continuously apply heat sufficient to at least maintain chemical 614 in liquid phase at the bottom portion 696 of delivery vessel 602 until refilling is complete. Housing 678 and/or lid 630 may be configured to transfer heat from heating devices 672, 680 and 686 to interior volume 684 to heat chemical 614. Heating devices 672, 680 and 686 may comprise any of a variety of heating devices (e.g., heaters, heating jackets, heating blocks, and/or radial heater) known to those of skill in the art and claimed subject matter is not limited in this regard.

Delivery vessel 602 may be configured to operate at an operating temperature based on a desired maintenance of chemical precursor/reactant, chemical 614 in liquid state. In some examples, the operating temperature is in the range of about 10° C. to about 500° C. Other temperature ranges are possible and claimed subject matter is not limited in this regard.

Once a refilling operation is complete, chemical 614 may form a solid at the bottom of delivery vessel 602 and may be stored there until a material processing operation. Chemical 614 may be cooled to a solidification temperature by a cooling device 688 coupled to delivery vessel 602 to maintain a temperature at the base of delivery vessel 602 sufficient to maintain chemical 614 in solid phase for storage. Cooling device 688 may comprise any of a variety of cooling devices including but not limited to a chill plate, cooling coils, variable pitch cooling coils, a cooling jacket, cooling fans, a Peltier cooler or integrated coolant channels circulating coolant or the like or any combination thereof. Alternatively, chemical 614 may be stored in a different form such as liquid. Heating devices 672, 680 and/or 686 may maintain chemical 614 in a liquid state at a temperature below the vaporization and/or sublimation point to store chemical 614 prior to a material processing operation.

In an example, during a material processing operation heating devices 672, 680 and/or 686 may be configured to heat chemical 614 to a temperature sufficient to change the phase of chemical 614, from liquid or solid, for example, by vaporizing and/or sublimating chemical 614. Once vaporized or sublimed, chemical 614 may be transported via chemical delivery line 628 to reaction chambers 622 and/or 624 for substrate processing. A carrier gas source 620 may be coupled to delivery vessel 602 via chemical delivery line 636 and may contain carrier gas 698. When introduced into delivery vessel 602, the carrier gas 698 helps transport vaporized and/or sublimed chemical reactants through vessel outlet 626 to substrate reaction chamber 622 and/or 624. Chemical delivery line 628 may comprise valves 632 and 634 for controlling fluid communication of chemical 614 and/or carrier gas from delivery vessel 602 to respective reaction chambers 622 and 624.

During material processing, delivery vessel 602 may be configured to operate at an operating temperature based on a desired subliming rate of chemical 614 chemical precursor/reactants. In some examples, the operating temperature is in the range of about 10° C.-500° C. Other temperature ranges are possible and claimed subject matter is not limited in this regard.

Once depleted of chemical 614, delivery vessel 602 may be refilled from remote refill vessel 604, repeating the above process until remote refill vessel is depleted. In some examples, it may not be necessary to completely deplete delivery vessel 602 of chemical 614 prior to refilling from remote refill vessel 604.

In an example, one or more back-up remote refill vessels 726 may be co-located with remote refill vessel 604 to reduce downtime required to replace remote refill vessel 602 when depleted. When remote refill vessel 604 needs to be replaced, back-up remote refill vessels 726 may be quickly coupled to delivery vessel 602 via chemical delivery line 606 (or via a different chemical delivery line) to avoid downtime waiting for remote refill vessel 604 to be removed and replaced. Alternatively, back-up remote refill vessels 726 may be coupled to remote refill vessel 604 at other opportune idle times, such as between refill operations or during upstream events requiring downtime on the substrate processing platform 610.

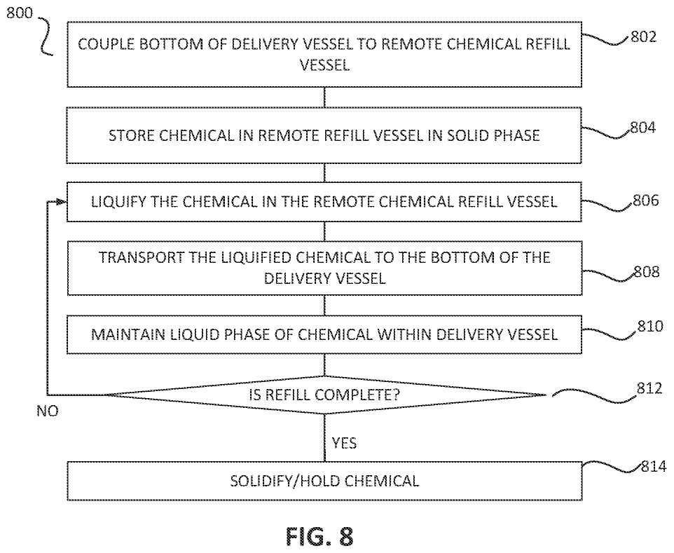

In the illustrated example controller 656 includes a device interface 662, a processor 664, a user interface 666, and a memory 668. The device interface 662 connects the processor 664 to the wired or wireless link 670. The processor 664 may be operably connected to the user interface 666 (e.g., to receive user input and/or provide user output therethrough) and may be disposed in communication with the memory 668. The memory 668 includes a non-transitory machine-readable medium having a plurality of program modules 690 recorded thereon containing instructions that, when read by the processor 664, cause the processor 664 to execute certain operations. Among the operations are operations of a material layer deposition method and methods for refilling a delivery vessel 602 (shown in FIG. 8), as will be described. As will be appreciated by those of skill in the art in view of the present disclosure, the controller 656 may have a different arrangement in other examples and remain within the scope of the present disclosure. In some embodiments, the electronics and/or computer elements for use in controlling one or more of reaction chamber 622, reaction chamber 624, delivery vessel 602 and/or remote refill vessel 604 can be found elsewhere in the system. For example, central controllers may control both apparatus of the one or more chambers themselves as well as control the valves that connect to the various vessels and any associated heaters. One or more valves may be used to control the flow of gas throughout substrate processing system 600.

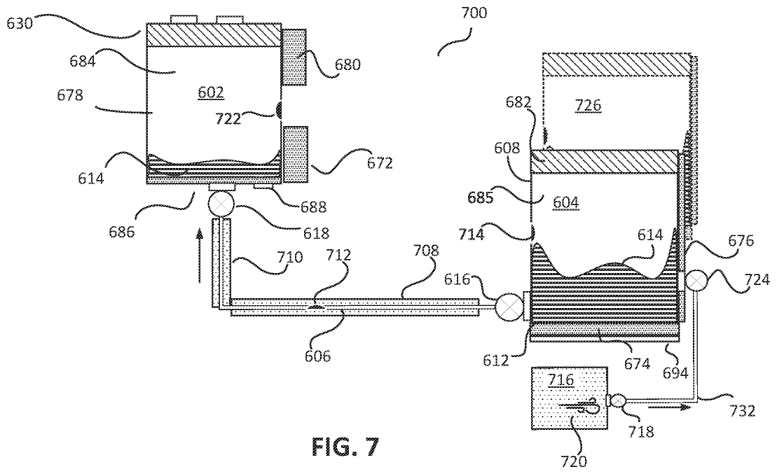

FIG. 7 is a schematic diagram illustrating an example refill subassembly 700 of substrate processing system 600 depicted in FIG. 6. Refill subassembly 700 includes delivery vessel 602 coupled to remote refill vessel 604 via chemical delivery line 606. Remote refill vessel 604 may be configured to maintain a temperature sufficient to store chemical 614 (e.g., precursor) in a solid state prior to being liquified, sublimed or vaporized. During storage, before a refilling operation, bottom portion 612 of the remote refill vessel 604 may be at a relatively low temperature. Cooling device 694 may be adapted to cool bottom portion 612 and may comprise any of a variety of cooling devices including but not limited to a chill plate, cooling coils, variable pitch cooling coils, a cooling jacket, cooling fans, a Peltier cooler or integrated coolant channels circulating coolant or the like or any combination thereof.

In an example, heating devices 708 and/or 710 may be coupled to chemical delivery line 606 to maintain a “transport temperature” which may be a liquification temperature to prevent solidification during transport. Such a transport temperature may be above a phase change (e.g., liquification) temperature. Heating devices 708 and/or 710 may be wrapped around, coiled, envelop, or otherwise be disposed in close proximity to chemical delivery line 606. Heating devices 708 and/or 710 may comprise heater jackets or other heating devices known to those of skill in the art and claimed subject matter is not limited in this regard. Chemical delivery line 606 may be arranged to have very few angles or corners to discourage solidification of chemical 614. Valves, connection points and/or other interruptions in the chemical delivery line 606 may be minimized to the extent possible to offset a higher risk of solidification in chemical delivery line 606 due to the disposition of remote refill vessel 604 distant from (i.e., spaced apart) from substrate processing platform 610 (see FIG. 6).

In an example, the refilling process may be controlled manually and/or refill operations may be partially or fully automated using a variety of sensors for automated feedback control by a controller 656 (see FIG. 6). For example, sensor 722 may be disposed adjacent to or within an interior volume 684 of delivery vessel 602, sensor 712 may be disposed within or adjacent to chemical delivery line 606 and sensor 714 may be disposed adjacent to or within an interior volume 685 of remote refill vessel 604. Sensors 712, 714, and/or 722 may monitor a variety of physical phenomenon such as, for example, acoustics, vibration, chemicals, moisture, flow, light, pressure, force, density, temperature and/or presence, or the like or any combinations thereof. Sensors 712, 714, and/or 722 may, for example, monitor the temperature of chemical 614 in delivery vessel 602, chemical delivery line 606, or remote refill vessel 604, or a combination thereof. Sensors 712, 714, and/or 722 may generate sensor data based on the monitoring and send the sensor data to controller 656 (see, FIG. 6) via communication link 670 to adjust a monitored parameter (e.g., temperature). For example, based on the sensor data, controller 656 may adjust one or more of heating devices 672, 674, 676, 680, 686, 708, and/or 710 and/or cooling devices 688 and 694 or the like or a combination thereof to bring chemical 614 within a preset temperature threshold value.

In some examples, a carrier gas source 716 may be coupled to remote refill vessel 604 via chemical delivery line 732 and may supply carrier gas 720 to remote refill vessel 604. Valves 718 and 724 may control the flow of carrier gas 720. Carrier gas 720 may increase pressure within remote refill vessel 604 to assist transport of the liquified chemical 614.

FIG. 8 is a flow chart that depicts an example solid source refill process 800. In an example, process 800 will be described with reference to FIGS. 6-7. Process 800 may begin at block 802, where delivery vessel 602 (see FIG. 6) may be coupled at a bottom portion 696 to a remote refill vessel 604 via a chemical delivery line 606. Delivery vessel 602 may be disposed at a first location on a substrate processing platform 610 and remote refill vessel 604 may be disposed in a second location remote from the substrate processing platform 610. Process 800 may continue at block 804, where a solid chemical 614 (e.g., precursor) may be stored in remote refill vessel at a first temperature in a first phase, as a solid. At block 806, chemical 614 may be liquified in remote refill vessel 604 at a second temperature by exposing chemical 614 to heat and/or pressure to convert the solid to a second phase, a liquid. In an example, the heat and/or pressure may be above a melting point of chemical 614. At block 808, chemical 614 may be transported to a bottom portion 696 of delivery vessel 602 in liquid phase to refill delivery vessel 602 with chemical 614. At block 810, chemical 614 may be maintained and held in delivery vessel 602 in liquid phase during transport of chemical 614 into delivery vessel by application of heat and/or pressure at or above the melting point of chemical 614. Process 800 may continuously return to block 806 until delivery vessel 602 is refilled. Blocks 806-810 may be performed simultaneously during filling process. Process 800 moves to block 812, upon completion of the refilling of delivery vessel 604 with chemical 614. At block 814, chemical 614 may be solidified by cooling bottom portion 696 of delivery vessel 602 to a temperature below the melting point of chemical 614. Chemical 614 may be held in delivery vessel until use in a material processing operation.

FIG. 9 is a flow chart that depicts an example process 900 which is an example embodiment of a solid source refill process 500 shown in FIG. 5. In an example, process 900 will be described with reference to FIGS. 1-4. Process 900 may begin at block 902, where delivery vessel 102 (see FIG. 1) may be coupled at a top portion 190 to a remote refill vessel 104 via a chemical delivery line 106. Delivery vessel 102 may be disposed at a first location on a substrate processing platform 110 and remote refill vessel 104 may be disposed in a second location remote from the substrate processing platform 110. Process 900 may continue at block 904, where a solid chemical 114 (e.g., precursor) may be stored in remote refill vessel at a first temperature in a first phase as a solid. At block 906, chemical 114 may be sublimed at a second temperature by exposing chemical 114 to heat and/or pressure to convert the solid to a second phase, a gas. In an example, the heat and/or pressure may be below a melting point of chemical 114. At block 908, chemical 114 may be transported to a top portion 190 of delivery vessel 102 in gas phase to refill delivery vessel 102 with chemical 114. At block 910, chemical 114 may be changed to a third phase wherein it may be liquified in top portion 190 of delivery vessel 102 by the application of heat and/or pressure at or above the melting point of chemical 114. At block 912, chemical 114 may be changed to a fourth phase, wherein it may be solidified on bottom interior surface 314 of delivery vessel 102. Liquification of chemical 114 causes formation of chemical 114 droplet 350. Droplets 350 fall to a bottom interior surface 314 of delivery vessel 102. At block 914, a temperature gradient may be maintained within delivery vessel 102. In particular, bottom interior surface 314 may be maintained at a solidification temperature of chemical 114 and may be held at the coolest temperature within the interior volume 180 of delivery vessel 102. Maintaining a temperature gradient within an inner volume of the delivery vessel wherein the top portion 190 of the delivery vessel 102 may be at a higher temperature than the bottom interior surface 314 enables simultaneous liquification of gaseous chemical 114 at top portion 190 of delivery vessel 102 and continued maintenance of the solid form of chemical 114 on bottom interior surface 314. Process 900 may continuously return to block 906 until delivery vessel 102 is refilled. Blocks 906-914 may be performed simultaneously during filling process. Process 900 moves to block 916 upon completion of the refilling of delivery vessel 102 with chemical 114. At block 918, solidified chemical 114 may be held in delivery vessel 102 until use in a material processing operation.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The headings provided herein, if any, are for convenience only and do not necessarily affect the scope or meaning of the devices and methods disclosed herein.

1. A method, comprising:
coupling a delivery vessel disposed at a first location on a substrate processing platform to a remote refill vessel disposed in a second location remote from the substrate processing platform;
storing a chemical in the remote refill vessel in a first phase;
changing a phase of the chemical in the remote refill vessel to a second phase; and
transporting the chemical in the second phase, to the delivery vessel.

2. The method of claim 1, wherein changing the phase of the chemical further comprises heating the chemical or pressurizing the chemical, or a combination thereof.

3. The method of claim 2, wherein changing the phase of the chemical further comprises sublimating the chemical at a first temperature below a melting point of the chemical.

4. The method of claim 3, wherein transporting the chemical further comprises:
receiving the chemical in the delivery vessel at a top portion of the delivery vessel in the second phase; and
heating the chemical to a second temperature or pressurizing the chemical, or a combination thereof, to change the phase of the chemical to a third phase.

5. The method of claim 4, further comprising:
receiving the chemical on a bottom surface of the delivery vessel in the third phase; and
modifying the temperature of the chemical to change the chemical to a fourth phase.

6. The method of claim 5, wherein the third phase is liquid and the fourth phase is solid.

7. The method of claim 6, further comprising maintaining a temperature gradient within an inner volume of the delivery vessel wherein the top portion of the delivery vessel is at a higher temperature than the bottom surface.

8. The method of claim 7, further comprising simultaneously changing the chemical to the third phase in the top portion of the delivery vessel and storing the chemical in the fourth phase on the bottom surface of the delivery vessel.

9. The method of claim 2, wherein changing the phase of the chemical further comprises liquifying the chemical at a first temperature above a melting point of the chemical.

10. The method of claim 9, wherein transporting the chemical further comprises:
increasing a pressure on the chemical subsequent to the liquification by exposing the chemical to a pressurized gas within a volume of the remote refill vessel;
receiving the chemical in the delivery vessel at a bottom portion of the delivery vessel in the second phase; and
heating the chemical to a second temperature above the first temperature.

11. A substrate processing system, comprising:
a delivery vessel having a first inner volume, disposed in a first location on a substrate processing platform;
a remote refill vessel in fluid communication with the delivery vessel via a chemical delivery line, the remote refill vessel comprising a second inner volume greater than the first inner volume and disposed in a second location remote from the substrate processing platform; and
a first heating device or a first pressurizing device, or a combination thereof, proximate the remote refill vessel, operable to heat or pressurize, or a combination thereof, a chemical disposed in the remote refill vessel sufficient to change a phase of the chemical from a first phase to a second phase.

12. The substrate processing system of claim 11, wherein the chemical delivery line is coupled to a second heating device operable to maintain the chemical delivery line at a transport temperature higher than a phase change temperature of the chemical.

13. The substrate processing system of claim 12, wherein the delivery vessel further comprises a third heating device, a second pressurizing device or a cooling device, or a combination thereof, wherein the chemical delivery line is coupled to the delivery vessel via an inlet valve disposed in a top portion or a bottom portion of the delivery vessel.

14. The substrate processing system of claim 13, further comprising:
at least one sensor disposed in the chemical delivery line, the delivery vessel or the remote refill vessel, or a combination thereof, to monitor a temperature of the chemical and generate sensor data based on the monitoring; and
at least one controller communicatively coupled to the at least one sensor and communicatively coupled to the first heating device, the second heating device, the third heating device, the first pressurizing device, the second pressurizing device or the cooling device, or a combination thereof,
the at least one controller configured to receive the sensor data and adjust the first heating device, the second heating device, the third heating device, the first pressurizing device, the second pressurizing device or the cooling device, or a combination thereof, based on the sensor data.

15. The substrate processing system of claim 14, wherein the inlet valve is disposed in the top portion of the delivery vessel and the third heating device or the second pressurizing device, or a combination thereof are configured to apply, respectively, heat or pressure, or a combination thereof, to the chemical upon entry into an interior volume of the delivery vessel, sufficient to change the phase of the chemical from the second phase to a third phase.

16. The substrate processing system of claim 15, wherein the cooling device is disposed at the bottom portion of the delivery vessel to cool a bottom interior surface to change a third phase of the chemical to a fourth phase.

17. The substrate processing system of claim 16, wherein the first phase is solid, the second phase is gas, the third phase is liquid, and the fourth phase is solid.

18. The substrate processing system of claim 14, wherein the inlet valve is coupled to the bottom portion of the delivery vessel, wherein the third heating device is disposed at a base portion of the delivery vessel and is configured to heat the chemical upon entry into an interior volume of the delivery vessel to maintain the second phase of the chemical during refill of the delivery vessel.

19. The substrate processing system of claim 18, wherein the first phase is a solid phase and the second phase is a liquid phase.

20. The substrate processing system of claim 13, wherein the cooling device comprises:
a cooling coil, disposed on an outer surface of the delivery vessel having a pitch that is varied along a longitudinal axis of the delivery vessel wherein the pitch is most dense proximate the bottom portion of the delivery vessel;
a coolant inlet coupled to the cooling coil, disposed proximate the bottom portion of the delivery vessel; and
a coolant outlet coupled to the cooling coils and disposed opposite the coolant inlet.
